(19) United States
(12) Patent Application Publication
(10) Pub. No.: US 2020/0111642 A1
(43) Pub. Date: Apr. 9, 2020

(54) GAS SUPPLY DEVICE

(71) Applicant: Toshiba Memory Corporation, Tokyo (JP)

(72) Inventor: Daiki IINO, Yokohama Kanagawa (JP)

(73) Assignee: Toshiba Memory Corporation, Tokyo (JP)

(21) Appl. No.: 16/279,986

(22) Filed: Feb. 19, 2019

(30) Foreign Application Priority Data
Oct. 5, 2018 (JP) 2018-190213

(51) Int. Cl. H01J 37/32; H01L 21/67

(52) U.S. Cl. CPC H01J 37/3244; H01J 2237/3341; H01L 21/67069

(57) ABSTRACT

According to one embodiment, a gas supply device includes at least one reservoir tank, which is to be connected to a process chamber configured to process a substrate and is configured to store a process gas to be supplied to the process chamber. A gas generator is configured to generate the process gas. A plurality of supply spaces is provided between the reservoir tank and the gas generator, is configured to receive the process gas from the gas generator, and supply the process gas in a pressurized state to the reservoir tank.

### CROSS-REFERENCE TO RELATED APPLICATIONS

This application is based upon and claims the benefits and priority from Japanese Patent Application No. 2018-190213, filed on Oct. 5, 2018, the entire contents of which are incorporated herein by reference.

### FIELD

Embodiments described herein relate generally to a gas supply device.

### BACKGROUND

Gas supply devices are generally used for a semiconductor manufacturing process or the like. The gas supply devices may obtain a process gas from a gas synthesis device. The gas synthesis device generates the process gas by using plasma and supplies the process gas to a process chamber.

However, since the internal pressure of the gas synthesis device is not very high, a pressure of the process gas to normally operate a mass flow controller cannot be obtained. Thus, a process gas may not be sufficiently supplied to a process chamber in some cases. If the amount of gas supplied from the gas synthesis device is less than an appropriate amount, a process in a process chamber may be hindered. On the other hand, if the amount of process gas produced by the gas synthesis device is too large, the extra process gas needs to be exhausted from the gas synthesis device. This wastes the process gas.

### DESCRIPTION OF THE DRAWINGS

FIG. 1 is a block diagram illustrating an example of a configuration of a semiconductor manufacturing device according to a first embodiment;

FIG. 2 is a table illustrating an example of an operation of the device according to the first embodiment;

FIG. 3 is a block diagram illustrating an example of a configuration of a semiconductor manufacturing device according to a second embodiment;

FIG. 4 is a table illustrating an example of an operation of the device according to the second embodiment;

FIG. 5 is a block diagram illustrating an example of a configuration of a semiconductor manufacturing device according to a third embodiment;

FIG. 6 is a table illustrating an example of an operation of the device according to the third embodiment;

FIG. 7 is a block diagram illustrating an example of a configuration of a semiconductor manufacturing device according to a fourth embodiment;

FIG. 8 is a table illustrating an example of an operation of the device according to the fourth embodiment;

FIG. 9 is a block diagram illustrating an example of a configuration of a semiconductor manufacturing device according to a fifth embodiment;

FIG. 10 is a table illustrating an example of an operation of the device according to the fifth embodiment;

FIG. 11 is a table illustrating an example of the operation of the device according to the fifth embodiment; and

FIG. 12 is a block diagram illustrating an example of a configuration of a semiconductor manufacturing device according to a sixth embodiment.

### DETAILED DESCRIPTION

In general, according to one embodiment, a gas supply device according to the present embodiment includes at least one reservoir tank, which is to be connected to a process chamber configured to process a substrate and is configured to store a process gas to be supplied to the process chamber. A gas generator is configured to generate the process gas. A plurality of supply spaces is provided between the reservoir tank and the gas generator, is configured to receive the process gas from the gas generator, and supply the process gas in a pressurized state to the reservoir tank.

Hereinafter, embodiments of the present disclosure will be described with reference to the drawings. The present embodiment does not limit the present disclosure. The drawings are schematic or conceptual, and the proportions of components are not necessarily the same as actual ones. In the specification and drawings, elements similar to those described before with reference to the drawings are denoted by the same reference numerals, and the detailed description thereof will be omitted as appropriate.

### First Embodiment

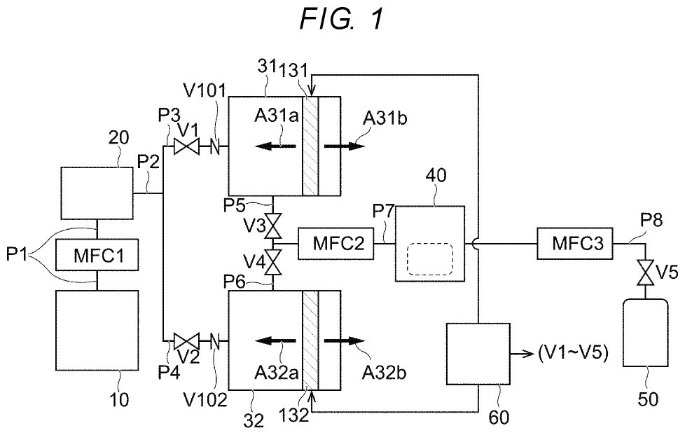

FIG. 1 is a block diagram illustrating an example of a configuration of a semiconductor manufacturing device (hereinafter, also simply referred to as a device) according to a first embodiment. The semiconductor manufacturing device according to embodiments below may be a device that processes a semiconductor substrate by using a process gas, such as an etching device, a deposition device. Hereinafter, descriptions will be given under an assumption that a semiconductor manufacturing device is an etching device for performing reactive ion etching (RIE).

The device includes a process chamber 10, a reservoir tank 20, two supply tanks 31 and 32, a gas generating unit (a gas generator) 40, mass flow controllers MFC1 to MFC3, valves V1 to V5, and a control unit 60. The reservoir tank 20, the two supply tanks 31 and 32, and the gas generating unit 40 may be configured as an etching device integrated with the process chamber 10, or may be configured as a gas supply device separate from the process chamber 10.

The process chamber 10 may accommodate a semiconductor substrate (not illustrated) to be etched and performs an etch process on the semiconductor substrate by using etching gas introduced from the reservoir tank 20. In case of etching a silicon oxide film, an etching gas as a process gas mainly includes, for example, at least one of CF-based gases, such as CF₄, C₂F₂, C₂F₄, C₂F₆, C₃F₅, C₄F₆, and C₄F₈.

The reservoir tank 20 is connected to the process chamber 10 via a pipe P1 and may store an etching gas to be supplied to the process chamber 10. A mass flow controller MFC1 is provided at the pipe P1 between the reservoir tank 20 and the process chamber 10, and measures the flow rate of the etching gas flowing through the pipe P1.

The supply tanks 31 and 32 as a plurality of supply spaces are connected in parallel between the reservoir tank 20 and the gas generating unit 40 via pipes P2 to P7. A supply tank 31 is connected to the reservoir tank 20 via pipes P2 and P3, and connected to the gas generating unit 40 via pipes P5 and P7. A supply tank 32 is connected to the reservoir tank 20 via pipes P2 and P4, and connected to the gas generating unit 40 via pipes P6 and P7. A pipe P2 is commonly connected between pipes P3 and P4 and the reservoir tank 20. A pipe P7 is commonly connected between pipes P5 and P6 and the gas generating unit 40.

The supply tanks 31 and 32 include movable partitioning plates 131 and 132, which are movable partitions, therein, respectively. A partitioning plate 131 is movable in the supply tank 31 in the direction of an arrow A31a or in the opposite direction A31b. The partitioning plate 131 may introduce an etching gas from the gas generating unit 40 into the supply tank 31 by moving in the direction A31b and may compress the etching gas by moving in the direction A31a. Furthermore, a partitioning plate 132 is movable in the supply tank 32 in the direction of an arrow A32a or in the opposite direction A32b. The partitioning plate 132 may introduce an etching gas from the gas generating unit 40 into the supply tank 32 by moving in the direction A32b and may compress the etching gas by moving in the direction A32a.

The internal volume of each of the supply tanks 31 and 32 is larger than the internal volume of the reservoir tank 20. Therefore, when the etching gas in the supply tank 31 or 32 is supplied to the reservoir tank 20, the etching gas is stored in the reservoir tank 20 in a compressed and pressurized state.

The supply tanks 31 and 32 alternately introduce the etching gas from the gas generating unit 40, and alternately supply the etching gas in a pressurized state to the reservoir tank 20. In order to enable such an operation, valves V1 to V4 are provided at pipes P3 to P6, respectively. A valve V1 is provided at a pipe P3 between a first supply tank 31 and the reservoir tank 20 to control the flow of the etching gas in the pipe P3. A valve V2 is provided at a pipe P4 between a second supply tank 32 and the reservoir tank 20 to control the flow of the etching gas in the pipe P4. A valve V3 is provided at a pipe P5 between the first supply tank 31 and the gas generating unit 40 to control the flow of the etching gas in the pipe P5. A valve V4 is provided at a pipe P6 between the second supply tank 32 and the gas generating unit 40 to control the flow of the etching gas in the pipe P6.

A check valve V101 is provided between the valve V1 and the supply tank 31, and a check valve V102 is provided between the valve V2 and the supply tank 32. The check valve V101 allows the etching gas to flow from the supply tank 31 to the reservoir tank 20, but prevents the flow of the etching gas in the opposite direction. The check valve V102 allows an etching gas to flow from the supply tank 32 to the reservoir tank 20, but prevents the flow of the etching gas in the opposite direction. As a result, check valves V101 and V102 prevent the backflow of an etching gas from the reservoir tank 20 to the supply tanks 31 and 32 when the valves V1 and V2 are open.

A mass flow controller MFC2 is provided at the pipe P7 between the supply tanks 31 and 32 and the gas generating unit 40, and measures the flow rate of an etching gas supplied from the gas generating unit 40 to the supply tank 31 or 32. A method for supplying the etching gas by the supply tanks 31 and 32 will be described below in more detail.

The gas generating unit 40 ionizes the source gas (for example, CF₄, C₄F₈, or the like) from a gas cylinder 50 to a plasma state under the pressure higher than the pressure in the process chamber 10 during an etching process. For example, assuming that the pressure in the process chamber 10 during the etching process is 10 mTorr to 100 mTorr (1 Torr=133.32 Pa), the pressure of the source gas in the gas generating unit 40 is 20 Torr to 400 Torr. By using a source gas of such high pressure, not only the source gas may be dissociated, but also a synthetic reaction may be performed. For example, the gas generating unit 40 may synthesize a high-order PFC gas (for example, C₄F₈) having a carbon-rich composition from the source gas CF₄. Although a high-order PFC gas is expensive, it is advantageous for forming a pattern with a high aspect ratio. Therefore, by synthesizing such a high-order PFC gas from a relatively inexpensive source gas, it is possible to form a pattern with a high aspect ratio while preventing an increase in the manufacturing cost of a semiconductor device.

The gas cylinder 50 is connected to the gas generating unit 40 via a pipe P8 and supplies the source gas to the gas generating unit 40. For example, the source gas is CF₄, C₄F₈, or the like, as described above. The gas cylinder 50 is detachably connected to the pipe P8. When the gas cylinder 50 is removed from the pipe P8, a valve V5 closes the pipe P8. When the gas cylinder 50 is attached to the pipe P8 to supply a source gas to the gas generating unit 40, the valve V5 opens the pipe P8.

A mass flow controller MFC 3 is provided at the pipe P8 located between the gas cylinder 50 and the gas generating unit 40, and measures the flow rate of the source gas supplied from the gas cylinder 50 to the gas generating unit 40.

The control unit 60 receives the flow rate or the like measured by the mass flow controllers MFC1 to MFC3 and controls the operations of the partitioning plates 131 and 132, the valves V1 to V5, and the check valves V101 and V102.

Next, the operation of the device will be described.

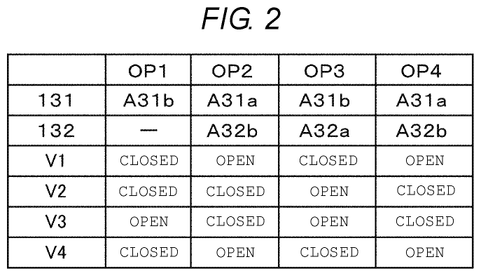

FIG. 2 is a table illustrating an example of an operation of the device according to the first embodiment. In the below embodiment, it is assumed that the gas cylinder 50 is attached to the pipe P8 and the valve V5 is already open. The valves V1 to V4 are closed as initial states. Furthermore, it is assumed that the gas generating unit 40 continuously generates the etching gas from the source gas from the gas cylinder 50.

First, in an operation OP1, the valve V3 is opened and the partitioning plate 131 moves in the direction A31b. As a result, the etching gas is introduced from the gas generating unit 40 to the supply tank 31. At this time, the partitioning plate 132 of supply tank 32 is not operating.

Next, in an operation OP2, the valve V3 is closed and valves V1 and V4 are opened. At this time, the partitioning plate 131 moves in the direction A31a, and the partitioning plate 132 moves in the direction A32b. As a result, the etching gas in the supply tank 31 is supplied to the reservoir tank 20 by the partitioning plate 131. Since the volume of the supply tank 31 is larger than the volume of the reservoir tank 20, the etching gas is supplied in a compressed and pressurized state into the reservoir tank 20. On the other hand, the etching gas in the gas generating unit 40 is introduced to the supply tank 32.

Next, in an operation OP3, the valves V1 and V4 are closed and valves V2 and V3 are opened. The partitioning plate 131 moves in the direction A31b, and the partitioning plate 132 moves in the direction A32a. As a result, the etching gas in the gas generating unit 40 is introduced to the supply tank 31. On the other hand, the etching gas in supply tank 32 is supplied to reservoir tank 20 by the partitioning plate 132. At this time, since the volume of the supply tank 32 is larger than the volume of the reservoir tank 20, the etching gas is supplied in a compressed and pressurized state into the reservoir tank 20. Furthermore, the etching gas may be supplied to the reservoir tank 20 after being pressurized in the supply tanks 31 and 32 or may be supplied to the reservoir tank 20 while being pressurized in the supply tanks 31 and 32.

Next, in an operation OP4, the valves V2 and V3 are closed and the valves V1 and V4 are opened. The partitioning plate 131 moves in the direction A31a and the partitioning plate 132 moves in the direction A32b. As a result, the etching gas in the supply tank 31 is supplied in a compressed and pressurized state into the reservoir tank 20 by the partitioning plate 131. On the other hand, an etching gas in the gas generating unit 40 is introduced to the supply tank 32.

Thereafter, the operations OP3 and OP4 are alternately and repeatedly executed.

Thus, according to the present embodiment, when the supply tank 31 supplies the process gas to the reservoir tank 20, the gas generating unit 40 supplies the process gas to the supply tank 32. On the contrary, when the supply tank 32 supplies the process gas to the reservoir tank 20, the gas generating unit 40 supplies the process gas to the supply tank 31. As a result, the supply tanks 31 and 32 can continuously supply the high pressure etching gas to the reservoir tank 20. The reservoir tank 20 can continuously store the high pressure etching gas and can supply a sufficient amount of etching gas for the etching process to the process chamber 10. Since the reservoir tank 20 can store the etching gas, it is not necessary to exhaust the etching gas generated by the gas generating unit 40. Therefore, the device 1 according to the present embodiment can supply an appropriate amount of gas at a sufficiently high pressure to the process chamber 10 without waste.

Since the etching gas is temporarily stored in the reservoir tank 20, radicals with short life endurances included in the etching gas as impurities are deactivated. Therefore, the concentration of the etching gas is increased.

### Second Embodiment

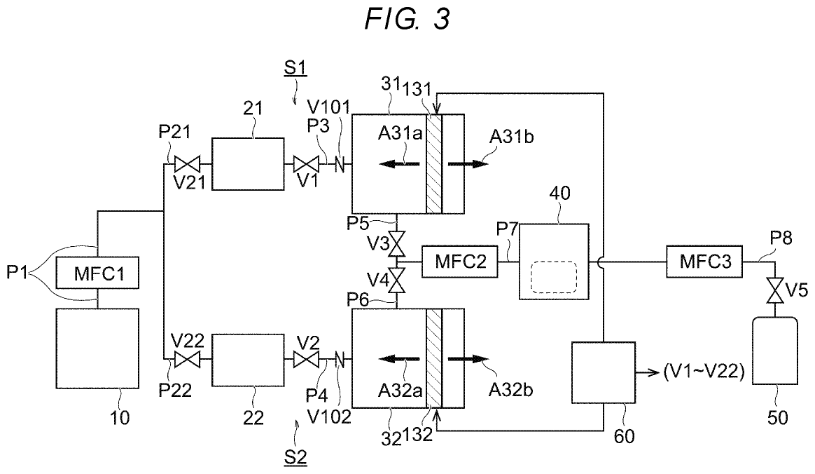

FIG. 3 is a block diagram illustrating an example of a configuration of a semiconductor manufacturing device (hereinafter, also simply referred to as a device) according to a second embodiment. The second embodiment is different from the first embodiment in that the reservoir tanks 21 and 22 are provided to correspond to the supply tanks 31 and 32, respectively.

A reservoir tank 21 as a first reservoir tank and the supply tank 31 are connected in series between the process chamber 10 and the gas generating unit 40, and constitute a first supply system S1. The reservoir tank 21 is connected to the process chamber 10 via pipes P21 and P1, and connected to the supply tank 31 via the pipe P3.

A reservoir tank 22 as a second reservoir tank and the supply tank 32 are connected in series between the process chamber 10 and the gas generating unit 40, and constitute a second supply system S2. The reservoir tank 22 is connected to the process chamber 10 via pipes P22 and P1, and connected to the supply tank 32 via the pipe P4.

The first and second supply systems S1 and S2 are connected in parallel between the process chamber 10 and the gas generating unit 40. The first and second supply systems S1 and S2 alternately introduce the etching gas from the gas generating unit 40, and alternately supply the etching gas to the process chamber 10. In order to enable such an operation, valves V21 and V22 are respectively provided at pipes P21 and P22 in addition to the valves V1 to V4. The valve V21 is provided at a pipe P21 between the reservoir tank 21 and the process chamber 10, and controls the flow of the etching gas in the pipe P21. The valve V22 is provided at a pipe P22 between the reservoir tank 22 and the process chamber 10, and controls the flow of the etching gas in the pipe P22. Other configurations of the second embodiment may be the same as corresponding configurations of the first embodiment.

Next, the operation of the device will be described.

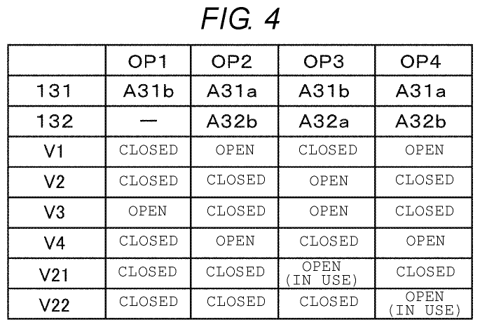

FIG. 4 is a table illustrating an example of an operation of the device according to the second embodiment.

First, in an operation OP1, the valve V3 is opened and the partitioning plate 131 moves in the direction A31b. As a result, the etching gas is introduced from the gas generating unit 40 to the supply tank 31. At this time, the partitioning plate 132 of supply tank 32 may not operate.

Next, in an operation OP2, the valve V3 is closed and valves V1 and V4 are opened. At this time, the partitioning plate 131 moves in the direction A31a, and the partitioning plate 132 moves in the direction A32b. As a result, the etching gas in the supply tank 31 is supplied to the reservoir tank 21 by the partitioning plate 131. Since the volume of the supply tank 31 is larger than the volume of the reservoir tank 21, the etching gas is supplied in a compressed and pressurized state into the reservoir tank 21. On the other hand, the etching gas in the gas generating unit 40 is introduced to the supply tank 32.

Next, in an operation OP3, the valves V1 and V4 are closed and valves V2, V3, and V21 are opened. The partitioning plate 131 moves in the direction A31b, and the partitioning plate 132 moves in the direction A32a. As a result, the etching gas in the gas generating unit 40 is introduced to the supply tank 31. On the other hand, the etching gas in the supply tank 32 is supplied to reservoir tank 22 by the partitioning plate 132. At this time, since the volume of the supply tank 32 is larger than the volume of the reservoir tank 22, the etching gas is supplied in a compressed and pressurized state into the reservoir tank 22. Furthermore, as the valve V21 is opened, the high pressure etching gas stored in the reservoir tank 21 in the operation OP2 is supplied to the process chamber 10. This etching gas is used for the etching process in the process chamber 10.

Next, in an operation OP4, the valves V2, V3, and V21 are closed and the valves V1, V4, and V22 are opened. The partitioning plate 131 moves in the direction A31a, and the partitioning plate 132 moves in the direction A32b. As a result, the etching gas in the supply tank 31 is supplied in a compressed and pressurized state into the reservoir tank 21 by the partitioning plate 131. On the other hand, the etching gas in the gas generating unit 40 is introduced to the supply tank 32. Furthermore, as the valve V22 is opened, the high pressure etching gas stored in the reservoir tank 22 in the operation OP3 is supplied to the process chamber 10. This etching gas is used for the etching process in the process chamber 10.

Thereafter, the operations OP3 and OP4 are alternately and repeatedly executed.

Thus, according to the second embodiment, while the reservoir tank 21 is supplying the etching gas to the process chamber 10, the supply tank 32 supplies the etching gas to the reservoir tank 22, and the gas generating unit 40 supplies the etching gas to the supply tank 31. On the other hand, when the reservoir tank 22 is supplying the etching gas to the process chamber 10, the supply tank 31 supplies the etching gas to the reservoir tank 21, and the gas generating unit 40 supplies the etching gas to the supply tank 32. As a result, the supply tanks 31 and 32 and the reservoir tanks 21 and 22 can continuously supply the high pressure etching gas to the process chamber 10, and supply a sufficient amount of etching gas for the etching process. Since the reservoir tanks 21 and 22 can store the etching gas, it is not necessary to exhaust the etching gas generated by the gas generating unit 40. Therefore, the second embodiment can obtain the same effect as in the first embodiment.

### Third Embodiment

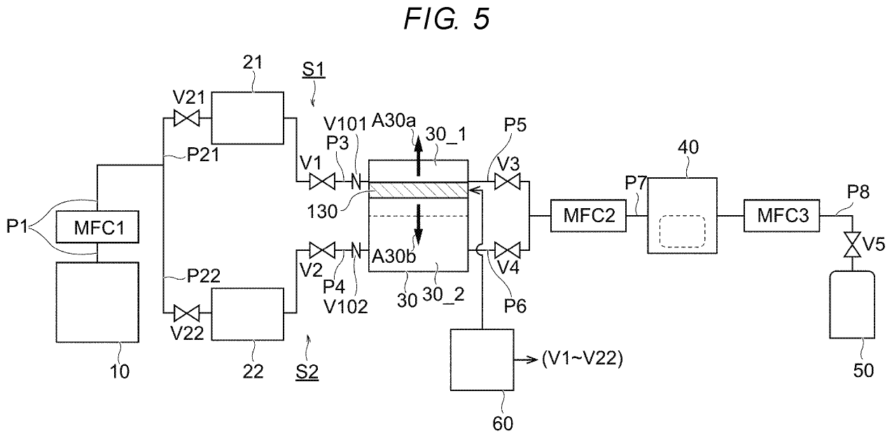

FIG. 5 is a block diagram illustrating an example of a configuration of a semiconductor manufacturing device 4 (hereinafter, also simply referred to as a device 4) according to a third embodiment. In the third embodiment, a supply tank 30 is integrated into one component, and a partitioning plate (a partition) 130 is provided therein. The partitioning plate 130 as a partitioning unit divides the internal space of the supply tank 30 into two spaces, and is movable in the internal space in the direction indicated by an arrow A30a or A30b.

The internal space of the supply tank 30 is partitioned into spaces 30_1 and 30_2 by the partitioning plate 130. The spaces 30_1 and 30_2, as a plurality of supply spaces, have functions similar to those of the supply tanks 31 and 32 in FIG. 3, respectively. Accordingly, the reservoir tank 21 and the space 30_1 as a first space are connected in series between the process chamber 10 and the gas generating unit 40, and constitute the first supply system S1. The reservoir tank 22 and the space 30_2 as a second space are connected in series between the process chamber 10 and the gas generating unit 40, and constitute the second supply system S2.

When the partitioning plate 130 moves in the direction A30a, the etching gas in the space 30_1 as the first supply space is supplied to the reservoir tank 21. On the other hand, at this time, the etching gas from the gas generating unit 40 is supplied to the space 30_2. When the partitioning plate 130 moves in the direction A30b, the etching gas in the space 30_2 as the second supply space is supplied to the reservoir tank 22. On the other hand, at this time, the etching gas from the gas generating unit 40 is supplied to the space 30_1. By repeating such operations, the supply tank 30 can continuously supply an etching gas to the reservoir tanks 21 and 22.

The supply tank 30 is configured such that the volumes of the spaces 30_1 and 30_2 when the etching gas is supplied are larger than the volumes of the reservoir tanks 21 and 22, respectively. For example, the position of the partitioning plate 130 when the etching gas from the gas generating unit 40 is supplied to the space 30_1 and the etching gas from the space 30_2 is supplied to the reservoir tank 22 is set as a first position. Also, the position of the partitioning plate 130 when the etching gas from the gas generating unit 40 is supplied to the space 30_2 and the etching gas from the space 30_1 is supplied to the reservoir tank 21 is set as a second position. In this case, when the partitioning plate 130 is located at the first position, the volume of the space 30_1 is larger than the volumes of the reservoir tanks 21 and 22 and the space 30_2. Also, when the partitioning plate 130 is located at the second position, the volume of the space 30_2 is larger than the volumes of the reservoir tanks 21 and 22 and the space 30_1. As a result, the supply tank 30 can supply the etching gas of the spaces 30_1 and 30_2 in a pressurized state to the reservoir tanks 21 and 22.

The first and second supply systems S1 and S2 are connected in parallel between the process chamber 10 and the gas generating unit 40. The first and second supply systems S1 and S2 alternately introduce the etching gas from the gas generating unit 40, and alternately supply the etching gas to the process chamber 10. Other configurations of the third embodiment may be the same as corresponding configurations of the second embodiment.

Next, the operation of the device will be described.

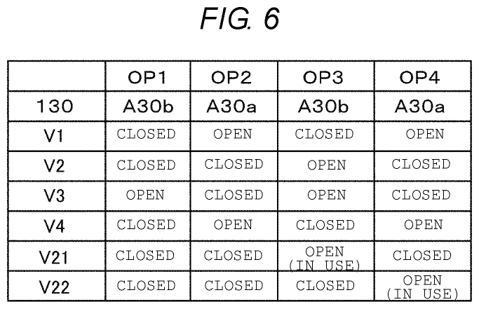

FIG. 6 is a table illustrating an example of an operation of the device according to the third embodiment. Also, the operations of valves V1 to V5, V21, and V22 are similar to the operations of those of the second embodiment.

First, in an operation OP1, the valve V3 is opened and the partitioning plate 130 moves in the direction A30b. Therefore, the etching gas is introduced to the space 30_1 from the gas generating unit 40.

Next, in an operation OP2, the valve V3 is closed and valves V1 and V4 are opened. Furthermore, the partitioning plate 130 moves in the direction A30a. As a result, the etching gas in the space 30_1 is supplied to reservoir tank 21 by the partitioning plate 130. Since the volume of the space 30_1 is larger than the volume of the reservoir tank 21, the etching gas is supplied in a compressed and pressurized state into the reservoir tank 21. On the other hand, the etching gas of the gas generating unit 40 is introduced to the space 30_2.

Next, in an operation OP3, the valves V1 and V4 are closed and valves V2, V3, and V21 are opened. Furthermore, the partitioning plate 130 moves in the direction A30b. Therefore, the etching gas in the gas generating unit 40 is introduced to the space 30_1. On the other hand, the etching gas in the space 30_2 is supplied to the reservoir tank 22 by the partitioning plate 130. Since the volume of the space 30_2 is larger than the volume of the reservoir tank 22, the etching gas is supplied in a compressed and pressurized state into the reservoir tank 22. Furthermore, as the valve V21 is opened, the high pressure etching gas stored in the reservoir tank 21 in the operation OP2 is supplied to the process chamber 10. This etching gas is used for the etching process in the process chamber 10.

Next, in an operation OP4, the valves V2, V3, and V21 are closed and the valves V1, V4, and V22 are opened. The partitioning plate 130 moves in the direction A30a. As a result, the etching gas in the space 30_1 is supplied in a compressed and pressurized state into the reservoir tank 21 by the partitioning plate 130. On the other hand, the etching gas in the gas generating unit 40 is introduced to the space 30_2. Furthermore, as the valve V22 is opened, the high pressure etching gas stored in the reservoir tank 22 in the operation OP3 is supplied to the process chamber 10. This etching gas is used for the etching process in the process chamber 10.

Thereafter, the operations OP3 and OP4 are alternately and repeatedly executed.

Thus, according to the third embodiment, the internal space of one supply tank 30 is partitioned into the plurality of spaces 30_1 and 30_2 by the partitioning plate 130. Thereafter, the supply tank 30 continuously supplies the etching gas from the plurality of spaces 30_1 and 30_2 to the plurality of reservoir tanks 21 and 22 by the operation of the partitioning plate 130. Even with such a configuration, an operation same as that of the second embodiment is possible. Therefore, the third embodiment can obtain the same effect as in the second embodiment. Furthermore, according to the third embodiment, the supply tank 30 is integrated into one component. Therefore, the overall size of the device is reduced.

### Fourth Embodiment

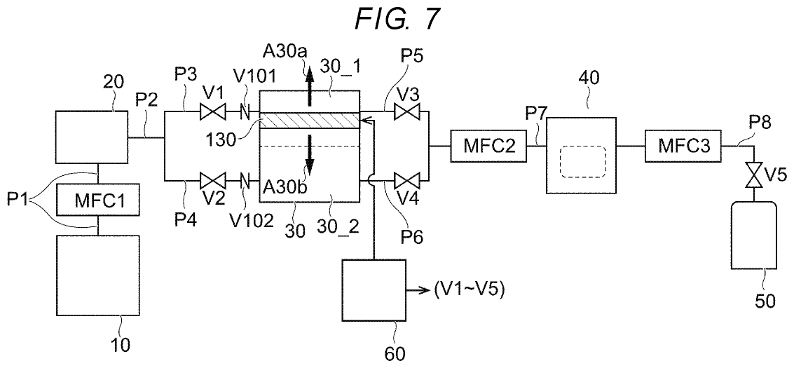

FIG. 7 is a block diagram illustrating an example of a configuration of a semiconductor manufacturing device (hereinafter, also simply referred to as a device) according to a fourth embodiment. In the fourth embodiment, the supply tank 30 of the third embodiment is provided instead of the supply tanks 31 and 32 of the first embodiment. In other words, the fourth embodiment is a combination of the third embodiment with the first embodiment. Other configurations of the fourth embodiment may be the same as corresponding configurations of the first embodiment. Therefore, detailed descriptions of the configuration of the fourth embodiment will be omitted.

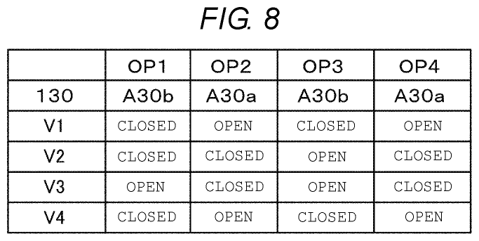

FIG. 8 is a table illustrating an example of an operation of the device according to the fourth embodiment. The supply tank 30 of the fourth embodiment operates in a manner similar to that of the supply tank 30 of the third embodiment, and the valves V1 to V4 of the fourth embodiment may operate in manners similar to those as the valves V1 to V4 of the first embodiment. Therefore, detailed descriptions of the operation of the fourth embodiment will be omitted. As a result, the supply tank 30 can continuously supply the high pressure etching gas to the reservoir tank 20. The fourth embodiment can also obtain the same effects as in the first and third embodiments.

### Fifth Embodiment

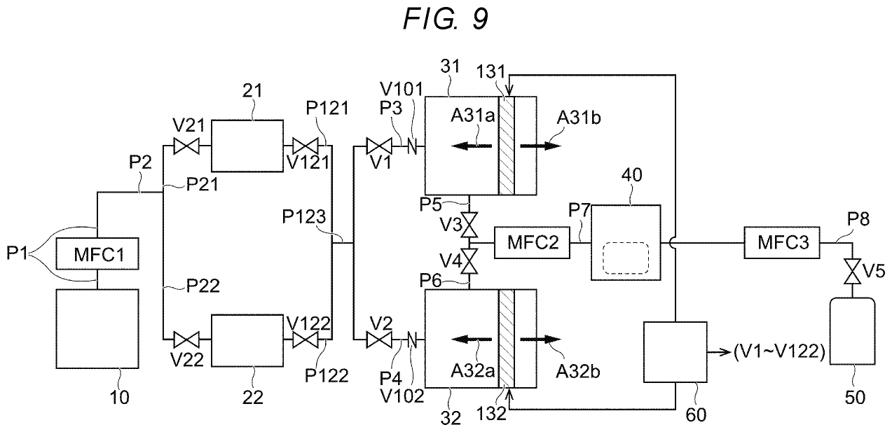

FIG. 9 is a block diagram illustrating an example of a configuration of a semiconductor manufacturing device (hereinafter, also simply referred to as a device) according to a fifth embodiment. The fifth embodiment is the same as the second embodiment in that a plurality of reservoir tanks 21 and 22 are provided to correspond to the supply tanks 31 and 32, respectively. However, the fifth embodiment is different from the second embodiment in the connection configuration of pipes between the reservoir tanks 21 and 22 and the supply tanks 31 and 32.

The pipes P3 and P4 are connected to a common pipe P123. The reservoir tanks 21 and 22 are connected to the common pipe P123 via pipes P121 and P122, respectively. Valves V121 and V122 are provided at the pipes P121 and P122, respectively. In this regard, the common pipe P123 may be partially provided between the reservoir tanks 21 and 22 and the supply tanks 31 and 32. When distances between the reservoir tanks 21 and 22 and the supply tanks 31 and 32 are long, the configuration of pipes between the reservoir tanks 21 and 22 and the supply tanks 31 and 32 can be simplified by providing the common pipe P123. Other configurations of the fifth embodiment may be the same as corresponding configurations of the second embodiment.

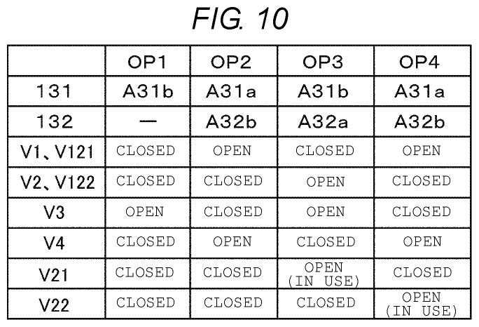

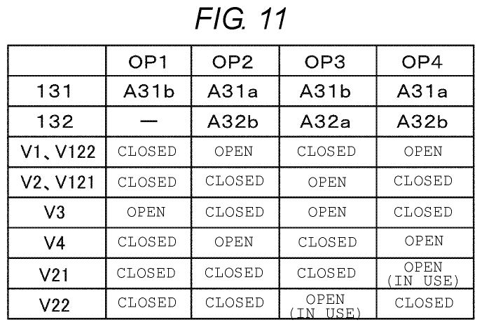

FIGS. 10 and 11 are tables illustrating examples of an operation of the device according to the fifth embodiment. The operation of the fifth embodiment may basically be the same as the operation of the second embodiment illustrated in FIG. 4. However, the valves V121 and V122 are alternately opened or closed in synchronization with the valves V1 and V2. As illustrated in FIG. 10, when valves V1 and V121 perform a same operation and valves V2 and V122 perform a same operation, the etching gas of the supply tank 31 is supplied to the reservoir tank 21 and the etching gas of the supply tank 32 is supplied to the reservoir tank 22.

On the contrary, as illustrated in FIG. 11, valves V1 and V122 may perform a same operation, and valves V2 and V121 may perform a same operation. In this case, the etching gas of the supply tank 31 is supplied to the reservoir tank 22, and the etching gas of the supply tank 32 is supplied to the reservoir tank 21. Therefore, the operations of the valves V21 and V22 are opposite to those operations illustrated in FIG. 10. In this way, as long as the etching gas is alternately supplied to the reservoir tank 21 and the reservoir tank 22, the etching gas of the supply tanks 31 and 32 may be supplied to either of the reservoir tanks 21 and 22.

Thus, even when the common pipe P123 is provided between the reservoir tanks 21 and 22 and the supply tanks 31 and 32, the same operation as in the second embodiment can be executed. Therefore, the fifth embodiment can obtain the same effect as in the second embodiment.

### Sixth Embodiment

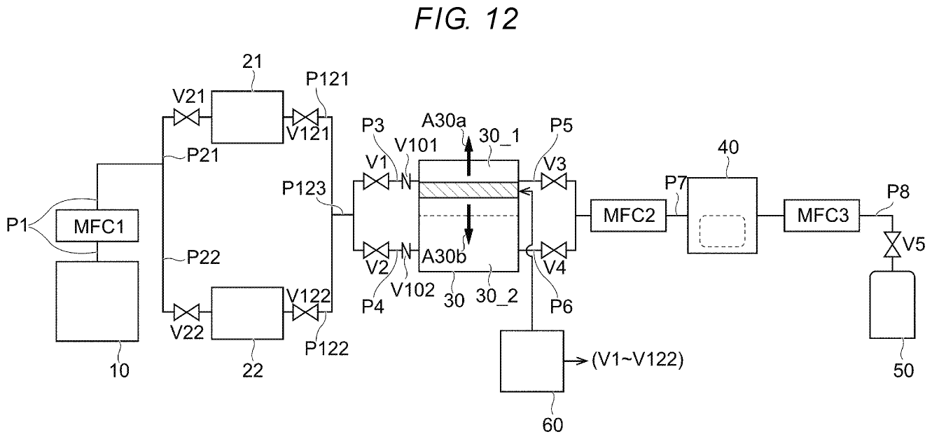

FIG. 12 is a block diagram illustrating an example of a configuration of a semiconductor manufacturing device (hereinafter, also simply referred to as a device) according to a sixth embodiment. In the sixth embodiment, the supply tank 30 of the fifth embodiment is provided instead of the supply tanks 31 and 32 of the fifth embodiment. In other words, the sixth embodiment is a combination of the third embodiment with the fifth embodiment. Other configurations of the sixth embodiment may be the same as corresponding configurations of the fifth embodiment. Therefore, detailed descriptions of the configuration of the sixth embodiment will be omitted.

The operation of the device according to the sixth embodiment may be implemented by combining the operation of the supply tank 30 illustrated in FIG. 6 with the operations of the valves V1 to V4, V21, V22, V121, and V122 illustrated in FIG. 10 or 11. In other words, the supply tank 30 of the sixth embodiment may operate in a manner similar to that of the third embodiment, and the valves V1 to V4, V21, V22, V121, and V122 of the sixth embodiment may operate in a manner similar to those of the fifth embodiment. Therefore, illustrations and detailed descriptions of the operation of the sixth embodiment will be omitted. As a result, the supply tank 30 can continuously supply the high pressure etching gas to the reservoir tanks 21 and 22. The sixth embodiment can also obtain the same effects as in the fifth embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A gas supply device comprising:
at least one reservoir tank to be connected to a process chamber configured to process a substrate, the at least one reservoir tank being configured to store a process gas to be supplied to the process chamber;
a gas generator configured to generate the process gas; and
a plurality of supply spaces between the at least one reservoir tank and the gas generator, the plurality of supply spaces being configured to receive the process gas from the gas generator, and supply the process gas in a pressurized state to the at least one reservoir tank.

2. The gas supply device according to claim 1, wherein
the plurality of supply spaces is connected in parallel between the at least one reservoir tank and the gas generator.

3. The gas supply device according to claim 1, wherein
when a first supply space among the plurality of supply spaces supplies the process gas to the at least one reservoir tank, the gas generator supplies the process gas to a second supply space among the plurality of supply spaces, and
when the second supply space supplies the process gas to the at least one reservoir tank, the gas generator supplies the process gas to the first supply space.

4. The gas supply device according to claim 1, wherein
the at least one reservoir tank comprises a plurality of reservoir tanks;
the plurality of reservoir tanks and the plurality of supply spaces are provided between the process chamber and the gas generator,
when a first reservoir tank among the plurality of reservoir tanks supplies the process gas to the process chamber, one of the plurality of supply spaces supplies the process gas to a second reservoir tank among the plurality of reservoir tanks and the gas generator supplies the process gas to another one of the plurality of supply spaces, and
when the second reservoir tank supplies the process gas to the process chamber, the another one of the plurality of supply spaces supplies the process gas to the first reservoir tank and the gas generator supplies the process gas to the one of the plurality of supply spaces.

5. The gas supply device according to claim 1, wherein
the at least one reservoir tank comprises a plurality of reservoir tanks;
the plurality of reservoir tanks and the plurality of supply spaces are provided between the process chamber and the gas generator, and
a first supply system includes a first reservoir tank among the plurality of reservoir tanks and a first supply space among the plurality of supply spaces that are connected in series,
a second supply system includes a second reservoir tank among the plurality of reservoir tanks and a second supply space among the plurality of supply spaces that are connected in series, and
the first supply system and the second supply system are connected in parallel between the process chamber and the gas generator.

6. The gas supply device according to claim 5, wherein
when the first supply system supplies the process gas to the process chamber, the gas generator supplies the process gas to the first supply system, and
when the second supply system supplies the process gas to the process chamber, the gas generator supplies the process gas to the second supply system.

7. The gas supply device according to claim 6, wherein
while the first supply system is supplying the process gas to the process chamber, the second supply space supplies the process gas to the second reservoir tank in the second supply system, and
while the second supply system is supplying the process gas to the process chamber, the first supply space supplies the process gas to the first reservoir tank in the first supply system.

8. The gas supply device according to claim 1, wherein the plurality of supply spaces comprises a plurality of supply tanks provided between the at least one reservoir tank and the process chamber.

9. The gas supply device according to claim 8, wherein
each of the plurality of supply tanks includes a partition dividing an internal space into a plurality of spaces, the partition being movable within the internal space.

10. The gas supply device according to claim 1, wherein
the plurality of supply spaces are provided in an internal space of one supply tank between the at least one reservoir tank and the gas generator, and
the one supply tank includes a partition dividing the internal space into the plurality of supply spaces and being movable within the internal space.

11. The gas supply device according to claim 10, wherein
the partition is movable within the internal space so as to be located at a first location when the process gas from the gas generator is supplied to a first supply space among the plurality of supply spaces and the process gas from a second supply space among the plurality of supply spaces is supplied to the at least one reservoir tank, and so as to be located at a second location when the process gas from the gas generator is supplied to the second supply space and the process gas from the first supply space is supplied to the at least one reservoir tank,
a volume of the first supply space is larger than a volume of the second supply space when the partition is located at the first location, and
the volume of the second supply space is larger than the volume of the first supply space when the partition is located at the second location.

12. The gas supply device according to claim 1, wherein
a volume of one supply space of the plurality of supply spaces when the one supply space is supplied with the process gas is larger than a volume of the at least one reservoir tank.

13. The gas supply device according to claim 8, wherein
a volume of one supply tank of the plurality of supply tanks is larger than a volume of the at least one reservoir tank.

14. A gas supply method using a gas supply device including at least one reservoir tank connected to a process chamber configured to process a substrate, a gas generator configured to generate a process gas used for processing the substrate, and a plurality of supply spaces provided between the at least one reservoir tank and the gas generator, the method comprising:
generating a process gas in the gas generator;
introducing the process gas from the gas generator to the plurality of supply spaces;
supplying the process gas in a pressurized state from the plurality of supply spaces to the at least one reservoir tank; and
supplying the process gas from the at least one reservoir tank to the process chamber.

15. The gas supply method according to claim 14, wherein
when a first supply space among the plurality of supply spaces supplies the process gas to the at least one reservoir tank, supplying, by the gas generator, the process gas to a second supply space among the plurality of supply spaces, and,
when the second supply space supplies the process gas to the at least one reservoir tank, supplying, by the gas generator, the process gas to the first supply space.

16. The gas supply method according to claim 14, wherein
the at least one reservoir tank comprises a plurality of reservoir tanks,
the plurality of reservoir tanks and the plurality of supply spaces are provided between the process chamber and the gas generator,
when a first reservoir tank among the plurality of reservoir tanks supplies the process gas to the process chamber, supplying, by one of the plurality of supply spaces, the process gas to a second reservoir tank among the plurality of reservoir tanks, and supplying, by the gas generator, the process gas to another one of the plurality of supply spaces, and
when the second reservoir tank supplies the process gas to the process chamber, supplying, by the another one of the plurality of supply spaces, the process gas to the first reservoir tank, and supplying, by the gas generator, the process gas to the one of the plurality of supply spaces.

17. The gas supply method according to claim 14, wherein
the at least one reservoir tank comprises a plurality of reservoir tanks,
the plurality of reservoir tanks and the plurality of supply spaces are provided between the process chamber and the gas generator,
a first supply system includes a first reservoir tank among the plurality of reservoir tanks and a first supply space among the plurality of supply spaces that are connected in series, and a second supply system includes a second reservoir tank among the plurality of reservoir tanks and a second supply space among the plurality of supply spaces that are connected in series, and the first supply system and the second supply system are connected in parallel between the process chamber and the gas generator,
when the first supply system supplies the process gas to the process chamber, supplying, by the gas generator, the process gas to the first supply system, and
when the second supply system supplies the process gas to the process chamber, supplying, by the gas generator, the process gas to the second supply system.

18. The gas supply method according to claim 14, wherein
the plurality of supply spaces are provided in an internal space of one supply tank provided between the at least one reservoir tank and the gas generator,
the one supply tank includes a partition dividing the internal space into the plurality of supply spaces, the partition being movable within the internal space,
when the partition moves to a first location, supplying the process gas from the gas generator to a first supply space among the plurality of supply spaces and supplying the process gas from a second supply space among the plurality of supply spaces to the at least one reservoir tank, and
when the partition moves to a second location, supplying the process gas from the gas generator to the second supply space and supplying the process gas from the first supply space to the at least one reservoir tank.

19. The gas supply method according to claim 18, wherein
a volume of the first supply space becomes larger than a volume of the second supply space when the partition moves to the first location, and
the volume of the second supply space becomes larger than the volume of the first supply space when the partition moves to the second location.

20. The gas supply method according to claim 14, wherein a volume of one supply space of the plurality of supply spaces when the one supply space is supplied with the process gas becomes larger than a volume of the at least one reservoir tank.
